(19) United States
(12) Patent Application Publication
(10) Pub. No.: US 2023/0296702 A1
(43) Pub. Date: Sep. 21, 2023

(54) ALL ELECTRICALLY OPERATED NANOMETER THREE-DIMENSIONAL MAGNETIC SENSOR AND ITS ARRAY AND MAGNETIC FIELD IMAGING METHOD

(71) Applicant: Huazhong University of science and technology, Wuhan (CN)

(72) Inventors: Long You, Wuhan (CN); Shihao Li, Wuhan (CN); Shuai Zhang, Wuhan (CN); Ruofan Li, Wuhan (CN)

(21) Appl. No.: 17/932,607

(22) Filed: Sep. 15, 2022

(30) Foreign Application Priority Data
Mar. 21, 2022 (CN) 202210279496.5

(51) Int. Cl. G01R 33/09; G01R 33/02

(52) U.S. Cl. CPC G01R 33/098; G01R 33/0206

(57) ABSTRACT

An all electrically operated nanometer three-dimensional magnetic sensor and its array and a magnetic field measurement method are disclosed. The magnetic sensor includes: a spin current generation layer, a magnetic material layer and an oxide layer in sequence from bottom to top, or a spin current generation layer and a magnetic tunnel junction or a spin valve in sequence from bottom to top. The magnetic sensor array includes a plurality of the magnetic sensors sharing a single spin current generation layer. The method includes: applying an excitation current pulse to a single magnetic sensor, counting the probability of the occurrence of a certain magnetization state in a random process of a bi-stable nanomagnet, based on a relationship between the probability and a magnetic field vector, calculating the magnitude of the components of the magnetic field vector in three-dimensional space direction.

### TECHNICAL FIELD

The present invention relates to the technical field of analysis and measurement method, and more particularly to an all electrically operated nanometer three-dimensional magnetic sensor and its array and a magnetic field imaging method.

### BACKGROUND ART

A magnetic sensor is a device that detects the magnitude and direction of the magnetic field intensity and then converts the field into an electrical signal. Currently magnetic sensors have a very wide range of applications. A magnetic sensor can be used for the detecting of current, power, position, distance, speed, angle, etc. Magnetic sensors have been widely used in industrial manufacturing, precision measurement, national defense and aviation, medical treatment, geography and other fields, and have a continuous broad application space.

The detection of weak magnetic fields at the nanoscale has a great application in scientific research, life medicine, electronic equipment, and the like. Detecting the three-dimensional magnetic field can obtain more information and more accurate information than the one-dimensional magnetic field. At present, nano-sized three-dimensional magnetic sensors have great application potentials in many application scenarios such as magnetoencephalography, molecular magnetic detection, material characterization, and magnetic spatial positioning.

At present, the commonly used magnetic sensors, including anisotropic magnetoresistive sensors, magnetosensitive diodes, Hall sensors, fluxgate magnetometers, etc., can detect the direction or intensity of the magnetic field, but there are some limitations. For example, the measurement accuracy of anisotropic magnetoresistive sensors is low, and a matching calibration algorithm is required; the fluxgate magnetometers are bulky and expensive; the sensitivity of magneto-sensitive diodes is low, and the signal output thereof is only about 0.05 mV/Oe, thus certain matching modules are needed, such as a signal amplification module. In addition, the sizes of these magnetic sensors are relatively large, and the spatial resolutions of the detected magnetic field are not high, which are all above the micron-meter level.

Moreover, the commonly used magnetic sensing technologies include Hall sensors, magnetic tunnel junction sensors based on tunneling magnetoresistance effect, quantum color center sensors based on nitrogen vacancies, and magnetic sensors based on superconducting quantum interferometers.

The Hall sensor has a simple structure and a wide measurement range. A single device of the magnetic tunnel junction sensor can achieve sub-micron size and sufficient sensitivity. However, a single device of these two types of magnetic sensors can only measure the magnetic field intensity in a single direction. Thus, in the case where a three-dimensional magnetic field is measured, a combination of three devices is generally required. Thus, the structure is more complex; in addition, the size may be greatly increased, which can be beyond the resolution of nanometer size.

Although magnetic sensors based on superconducting quantum interference device have achieved nano-scale magnetic detection, they can only measure a one-dimensional magnetic field. In addition, the superconducting materials need to work at very low temperatures. Hence, cryogenic facilities also greatly increase the size and complexity of the device.

A quantum magnetic sensor based on nitrogen vacancies senses the magnetic field through a quantum color center. It has the highest spatial resolution and an extremely high sensitivity. However, complex optical and microwave equipment is generally required to assist in use. Its structure is relatively complex and cannot be integrated into portable devices and integrated circuit chips. In addition, since the nitrogen vacancy color centers used are generally generated at random positions by irradiation, the characteristics of different devices are also random, which is not suitable for the integration to form an array.

### SUMMARY OF THE INVENTION

To improve the existing magnetic sensor technologies, the present invention provides an all electrically-operated nanometer three-dimensional magnetic sensor, an array thereof, and a magnetic field measurement method thereof. The object of the present invention is to achieve the measurement of an external vectorial magnetic field with a single nano-device.

To achieve the above object, according to a first aspect of the present invention, nanoscale three-dimensional magnetic sensor with all-electric operation is provided; from bottom to top, the magnetic sensor comprises: a spin current generation layer, a magnetic material layer, and an oxide layer; the spin current generation layer comprises a cross-shaped conductive channel for conducting current; the magnetic material layer is a single magnetic domain nanomagnet and has magnetic anisotropy perpendicular to a surface thereof under an action of the oxide layer;
or from bottom to top, the magnetic sensor comprises: a spin current generation layer, a free layer, a tunneling layer, and a fixed layer; the free layer, the tunneling layer and the fixed layer constitute a magnetic tunnel junction, and the free layer is a single magnetic domain nanomagnet with magnetic anisotropy perpendicular to a surface thereof;
or from bottom to top, the magnetic sensor comprises: a spin current generation layer, a first magnetic layer, a non-magnetic intermediate layer, a second magnetic layer, and a pinning layer; the first magnetic layer, the non-magnetic intermediate layer, the second magnetic layer and the pinning layer constitute a spin valve, and the first magnetic layer is a single magnetic domain nanomagnet with magnetic anisotropy perpendicular to a surface thereof.

Furthermore, a protective layer is further provided on the oxide layer for isolating air.

Furthermore, a material of the spin current generation layer is a heavy metal material or a topological insulator material.

Furthermore, a material of the nanomagnet is CoFeB, CoMnSi, CoFeSi, CoFeAl, GaMnAs, CoFeAlSi, CoFe, FePt, CoPt, FeNi, Fe, Co, or Ni.

Furthermore, a material of the oxide layer is MgO or Al₂O₃;
a material of the tunneling layer is MgO, Al₂O₃, AlO, TiO₂, HfO₂, MgAlO₄, AlN, or BN;
a material of the first magnetic layer and the second magnetic layer is CoFeB, CoMnSi, CoFeSi, CoFeAl, GaMnAs, CoFeAlSi, CoFe, FePt, CoPt, FeNi, Fe, Co, or Ni;
a material of the non-magnetic intermediate layer (301) is Cu, Cr, Ru, or Ag; and
a material of the pinning layer is FeMn, IrMn, NiMn, PtMn, or NiO.

According to a second aspect of the present invention, a three-dimensional magnetic field measurement method is provided, the magnetic sensor according to the first aspect is used in the method; the method includes:
establishing a three-dimensional rectangular coordinate system: establishing a three-dimensional rectangular coordinate system with a direction of the cross-shaped conductive channel as an x-axis and a y-axis thereof, and a direction perpendicular to a surface of the spin current generation layer as a z-axis;
in the cross channel of the spin current generation layer, applying an excitation current pulse to a positive direction and a negative direction of the x-axis and the y-axis respectively, so that the spin current generation layer generates a spin-polarized current, applying a spin-orbit torque to the nanomagnet, so that a direction of the magnetic moment of the nanomagnet is tuned to hard axis; removing the excitation current pulse, and under an external magnetic field, the magnetization state of the nanomagnet randomly returning to be perpendicular to the surface thereof upward or downward with a certain probability; and then adding a read current pulse to measure an anomalous Hall voltage at both ends of the spin current generation layer, the resistance of the magnetic tunnel junction, or the resistance of the spin valve to determine the magnetization state of the nanomagnet; and repeating the foregoing operation;
calculating probabilities: counting a number of occurrences of a certain magnetization state, and then calculating probabilities of the occurrence of certain magnetization states when the excitation current pulse is applied in corresponding directions, which are denoted as Pₓ₊, Pₓ₋, P_{y+}, P_{y-} respectively; adding the probabilities Pₓ₊ and Pₓ₋, to get a probability P₁ of the magnetization state in a case equivalent to a magnetic field being applied in the z direction; subtracting the probability Pₓ₋ from the probability Pₓ₊ to get a probability P₂ of the magnetization state in a case equivalent to a magnetic field being applied in the x direction; and subtracting the probability of P_{y-} from the probability P_{y+} to get the probability P₄ of the magnetization state in a case equivalent to a magnetic field being applied in the y direction; and
calculating a magnetic field vector: bringing the probabilities P₁, P₂ and P₄ into a functional relationship between the probability of the occurrence of the magnetization state and the magnetic field vector to obtain the magnitudes of the external magnetic field in three directions; and then through vector reconfiguring, obtaining the magnetic field vector.

Furthermore, the functional relationship between the probability of the occurrence of the magnetization state and the magnetic field vector is obtained to measure a detected magnetic field, comprising the following steps:

step S1, applying an excitation currents pulse to the positive direction and negative direction of the x-axis, and the positive direction and negative direction of the y-axis respectively;

step S2, in each current direction, applying a detected vectorial magnetic field along the x, y, and z directions respectively;

step S3: calculating a probability that a certain magnetization state occurs when applying the detected magnetic field along the x, y, and z directions respectively in each current direction, and then establishing a relationship between the probability and the magnitude and direction of the detected magnetic field; and

step S4, based on a relational formula, obtaining a functional relational formula between the probability of the occurrence of the magnetization state and the vectorial magnetic field.

Furthermore, when measuring the anomalous Hall voltage, the direction for applying the read current pulse are the same as that of the excitation current pulse; and when measuring the resistance of the magnetic tunnel junction or the resistance of the spin valve, the read current pulse is applied to the tunnel junction or the spin valve in the z-axis direction.

According to a third aspect of the present invention, nanometer three-dimensional magnetic sensor array with all electric-operation is provided, the magnetic sensor array includes a plurality of magnetic sensors according to the first aspect, and the plurality of the magnetic sensors share a single spin current generation layer.

According to a fourth aspect of the present invention, a scanning probe with the function of mapping three-dimensional magnetic field is provided, and the magnetic sensor according to the first aspect is integrated on a probe.

In general, through the above technical solutions provided by the present invention, the following beneficial effects can be achieved:

(1) The three-dimensional magnetic sensor of the present invention changes the direction of the magnetic moment of a single magnetic domain nanomagnet by applying an excitation current pulse on the spin current generation layer; under the action of the external magnetic field, the magnetization state is perpendicular to the surface upward or downward with a certain probability, and the probability of a certain magnetization state of the bi-stable nanomagnet in the random process is calculated; according to the relationship between the probability and the magnetic field vector, the magnitude of the components of the magnetic field vector in the three-dimensional directions can be calculated. That is, the present invention realizes the measurement of the magnitude of the components of the magnetic field vector in the three-dimensional space through a single nano-device. Meanwhile, since the magnetic sensor of the present invention is a nano-device, it can realize nano-scale measurement, has high spatial resolution and small size, and is easy to integrate on a large scale.

(2) The magnetic field measurement method of the present invention only needs to apply a current pulse to read the anomalous Hall voltage at both ends of the spin current generation layer, the resistance of the magnetic tunnel junction or the resistance of the spin valve for different structures of the three magnetic sensors. The measurement is performed in an all electrical way and does not require complex algorithms. The measurement method is simple and does not require additional auxiliary devices. In addition, the measurement results are accurate.

(3) Moreover, multiple magnetic sensors can be jointly integrated on a spin current generation layer to obtain a magnetic sensor array with high density and high spatial resolution. This reduces the distance between the magnetic sensors to tens of nanometers, which can be used for magnetic field measurement or magnetic imaging in a large range of space.

(4) Furthermore, by integrating the magnetic sensor of the present invention into the tip of an atomic force microscope probe, scanning imaging of magnetic information on the surface of a material can be realized.

In summary, the present invention realizes the three-dimensional vector measurement of an external magnetic field by a single device. In addition, the device has nanometer size and nanometer spatial resolution. Thus, the present invention expands the application potential in many fields such as chip integration, microscopic magnetic detection, magnetic imaging, magnetic positioning, and molecular magnetic detection.

### BRIEF DESCRIPTION OF THE DRAWINGS

FIG. 1 is a schematic diagram of a first structure of the magnetic sensor provided by the present invention.

FIG. 2 is a schematic diagram of a second structure of the magnetic sensor provided by the present invention.

FIG. 3 is a schematic diagram of a third structure of the magnetic sensor provided by the present invention.

FIG. 4 is a schematic diagram of the principle of spin-orbit torque.

FIG. 5 is a schematic diagram of the principle of the anomalous Hall effect.

FIG. 6 shows the two states of a magnetic tunnel junction in the tunneling magnetoresistance effect; the left panel shows the tunnel junction in a high resistance state, and the right panel shows the tunnel junction in a low resistance state.

FIG. 7 is a schematic diagram of a random switching process of the sensor.

FIG. 8 is a schematic diagram of current application in a process of measuring the magnetic field of the first magnetic sensor structure provided by the present invention.

FIG. 9 is a schematic diagram of current application in a process of measuring the magnetic field of the second magnetic sensor structure provided by the present invention.

FIG. 10 is a schematic diagram of current application in a process of measuring the magnetic field of the third magnetic sensor structure provided by the present invention.

FIG. 11 is a schematic diagram of the applied current pulse when the sensor measures the three-dimensional vector of a magnetic field.

FIG. 12 shows the probability of the downward magnetization state as a function of the magnetic field along the x, y, and z directions, respectively, when an excitation current is applied on the x-axis.

FIG. 13 shows the probability of the downward magnetization state as a function of the magnetic field along the x, y, and z directions, respectively, when an excitation current is applied on the y-axis.

FIG. 14 shows the calculated probability as a function of the components of magnetic field vector along x, y and z directions, where the direction of magnetic field vector is arbitrary.

FIG. 15 is a schematic diagram of a magnetic sensor array provided by the present invention.

FIG. 16 is a schematic diagram of a scanning probe of an atomic force microscope integrated with a three-dimensional magnetic sensor provided by the present invention.

Throughout the drawings, the same reference numbers are used to refer to the same elements or structures, in the figures:
101—spin current generation layer, 102—magnetic material layer, 103—oxide layer, 104—protective layer, 200—free layer, 201—tunneling layer, 202—fixed layer, 300—first magnetic layer, 301—non-magnetic intermediate layer, 302—second magnetic layer, 303—pinning layer.

### DESCRIPTION OF THE EMBODIMENTS

In order to make the objectives, technical solutions and advantages of the present invention clearer, the present invention will be further described in detail below with reference to the accompanying drawings and specific embodiments. It should be understood that the specific embodiments described herein are only used to explain the present invention, but not to limit the present invention. In addition, the technical features involved in various embodiments of the present invention as described below can be combined with each other as long as there is no conflict therebetween.

In the present invention, the terms “first,” “second” and the like in the description and the accompanying drawings are used to distinguish similar objects, and are not necessarily used to describe a specific order or sequence.

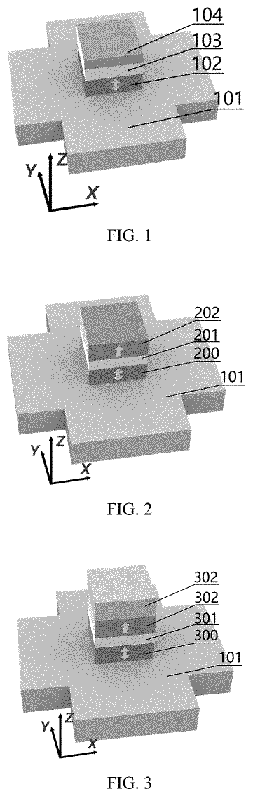

For the convenience of description, in the present invention, according to the geometric characteristics of the magnetic sensor, a three-dimensional space rectangular coordinate system as shown in FIG. 1, FIG. 2, and FIG. 3 is established. A direction perpendicular to the spin current generation layer 101 and from the spin current generation layer 101 to the nanomagnetic material layer is defined as a positive z-axis direction. The directions of the two conductive channels of the spin current generation layer 101 are selected to be the x-axis and y-axis directions, respectively. As shown in FIG. 1, the magnetic sensor of the first structure provided by the present invention is prepared from a thin film stacked with multiple layers of materials. It includes from bottom to top: a spin current generation layer 101, a magnetic material layer 102, and an oxide layer 103.

The spin current generation layer 101 has two mutually perpendicular conductive channels for conducting current. Preferably, the spin current generation layer 101 is of a cross shape.

The magnetic material layer 102 is a single magnetic domain nanomagnet located in the center of the spin current generation layer 101. In addition, its magnetic anisotropy axis is perpendicular to the plane of the nanomagnetic material layer. It has two stable magnetization states, upward or downward magnetization perpendicular to the nanomagnetic material layer.

The oxide layer 103 is used to assist the nanomagnetic material layer to obtain the magnetic anisotropy axis perpendicular to the thin film.

Preferably, the material of the spin current generation layer 101 can be a heavy metal material, such as Ta, Pt, W, Mo, Pd, or Nb, or a topological insulator material, such as Bi₂Se₃, α-Sn, Sb₂Te₃, Bi₂Te₃, BiₓSb₂₋ₓTe₃, Bi₂Te₂Se.

Preferably, the material of the magnetic material layer 102 can be CoFeB, CoMnSi, CoFeSi, CoFeAl, GaMnAs, CoFeAlSi, CoFe, FePt, CoPt, FeNi, Fe, Co or Ni.

Preferably, the material of the oxide layer 103 is MgO or Al₂O₃.

Preferably, a protective layer 104 is further provided on the oxide layer 103, and the material thereof is preferably a metal or an oxide. It is used to isolate the air to protect the sensor and prevent the material from being oxidized.

As shown in FIG. 2, the magnetic sensor of the second structure is provided by the present invention. It includes from bottom to top: a spin current generation layer 101, a free layer 200, a tunneling layer 201, and a fixed layer 202. The free layer, the tunneling layer and a pinning layer constitute a magnetic tunnel junction. The free layer is a nanomagnetic material. It acts as a nanomagnet that can sense a magnetic field, with magnetic anisotropy perpendicular to its surface. Preferably, the material of the free layer and the fixed layer can be CoFeB, CoMnSi, CoFeSi, CoFeAl, GaMnAs, CoFeAlSi, CoFe, FePt, CoPt, FeNi, Fe, Co or Ni. The types of the insulating material of the tunneling layer include MgO, Al₂O₃, AlOx, TiO₂, HfO₂, MgAlO₄, AlN or BN. Preferably, an auxiliary structure for fixing the magnetization state of the upper fixed layer, a conductive electrode or a protective layer made of a metal or semiconductor material can be further arranged on the magnetic tunnel junction.

As shown in FIG. 3, the magnetic sensor of the third structure provided by the present invention includes from bottom to top: a spin current generation layer 101, a first magnetic layer 300, a non-magnetic intermediate layer 301, a second magnetic layer 302, and a pinning layer 303. The first magnetic layer, the non-magnetic intermediate layer, the second magnetic layer, and the pinning layer constitute a spin valve. The first magnetic layer is a nanomagnetic material. In addition, as a nanomagnet that senses a magnetic field, it has magnetic anisotropy perpendicular to its surface.

Preferably, the material of the first magnetic layer and the second magnetic layer can be CoFeB, CoMnSi, CoFeSi, CoFeAl, GaMnAs, CoFeAlSi, CoFe, FePt, CoPt, FeNi, Fe, Co or Ni. The non-magnetic interlayer material can be Cu, Cr, Ru, Ag. In addition, the material of the pinning layer can be FeMn, IrMn, NiMn, PtMn, or NiO.

In practical applications, the three-dimensional magnetic sensor may further include a substrate layer as a support.

When measuring an external magnetic field, excitation current pulses are respectively applied to the positive and negative directions along the conductive channel of the cross-shaped in the spin current generation layer, so that the spin current generation layer generates a spin polarized current to apply a spin-orbit torque to the nanomagnet, thereby changing the direction of the magnetization of the nanomagnet; under the action of an external magnetic field, the magnetization state of the nanomagnet is perpendicular to its surface upward or downward with a certain probability; then the magnetization state of the nanomagnet is detected by the magnitude of the anomalous Hall voltage at both ends of the spin current generation layer, the magnitude of the resistance of the magnetic tunnel junction, or the magnitude of the resistance of the spin valve; the probability of the occurrence of a certain magnetization state is then calculated, thus the magnitude and direction of the external magnetic field can be obtained according to the functional relationship between the probability and the magnetic field vector.

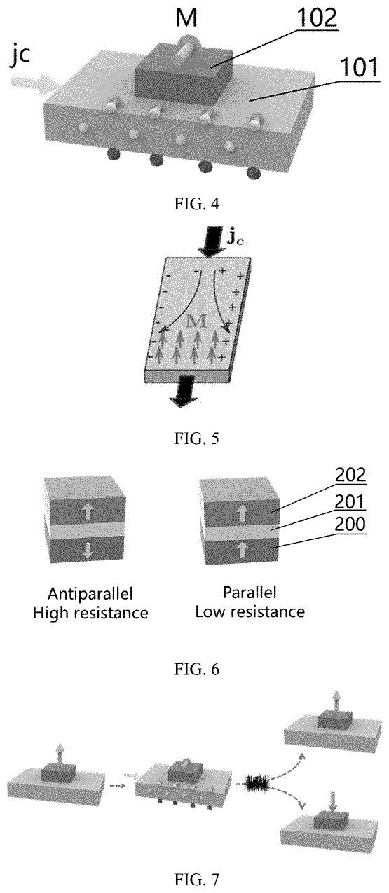

Specifically, as shown in FIG. 4, j_{c} represents the current density, and M represents the magnetization vector of the nanomagnet (that is, the nanomagnetic material layer or free layer). The spin-orbit torque originates from the spin Hall effect or the Rashba effect. In the spin current generation layer 101 and the magnetic material structure adjacent to the spin current generation layer, when a current flows through the spin current generation layer, a spin polarized current will be generated on the upper and lower surfaces of the spin current generation layer. When the spin-polarized current enters the adjacent nanomagnetic material layer, it will have a torque effect on the nanomagnetic material layer to change the direction of its magnetization. As shown in the figure, the magnetic moment is pulled into the plane of the nanomagnetic material layer film perpendicular to the direction of the current flowing therein.

As shown in FIG. 5, for the first structure of the present invention, when current flows through the nanomagnet, a transverse voltage can be generated perpendicular to the current and the magnetization direction of the magnet. The magnitude of the voltage is related to the direction and magnitude of the magnetization of the nanomagnet, so that the magnetization state of the magnet can be detected by the magnitude of the voltage.

As shown in FIG. 6, for the second structure of the present invention, the magnetic tunnel junction includes two layers of thin conductive and magnetic materials (that is, the fixed layer 202 and the free layer 200) and a very thin layer of insulating material (the tunneling layer 201) therebetween. The coercive force of the magnetic material in the fixed layer is relatively large, and the magnetization thereof is generally fixed. The magnetization of the magnetic material in the free layer is often controlled to vary. When electrons are transferred between the free layer and the pinning layer, that is, when the current flows through the magnetic tunnel junction, the electrons pass through the tunneling layer in the middle; in such a case, if the magnetization directions of the pinning layer and the free layer are parallel, the scattering of the electrons when passing two layers is relatively small, so the current is relatively large, and the magnetic tunnel junction is in a low resistance state. On the contrary, if the magnetization directions of the two are antiparallel to each other, the electrons can be greatly scattered when they are transferred from one layer to the other layer, so the current is relatively small and the magnetic tunnel junction is in a high resistance state. The magnetization direction of the fixed layer remains unchanged. As a result, it is possible to determine whether the magnetization of the fixed layer and the free layer is parallel or antiparallel based on the magnitude of the resistance, and then the magnetization direction of the free layer can be detected.

Similar to the second structure described above, for the third structure of the present invention, the current passing through the spin valve is also scattered by the magnetic layer; the difference is that the current travels through the non-magnetic intermediate layer by conduction rather than tunneling. When the magnetization direction of the first magnetic layer is parallel to the magnetization direction of the second magnetic layer, the spin valve has a relatively small resistance value; when the magnetization direction of the first magnetic layer is opposite to the magnetization direction of the second magnetic layer, the spin valve has a relatively large resistance value, that is, the giant magnetoresistance effect. At the same time, the second magnetic layer is subjected to the antiferromagnetic coupling effect of the pinning layer, and has a high coercivity. The magnetization direction is generally unchanged. As a result, the magnetization direction of the first magnetic layer can be detected by the magnitude of the resistance.

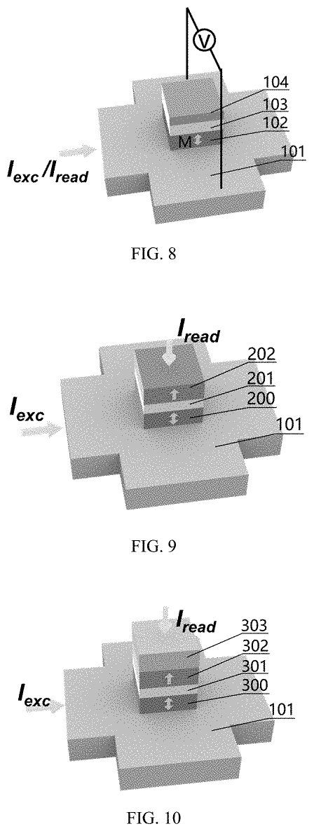

In the present invention, a relatively large current pulse is applied on one of the two channels of the cross in the spin current generation layer, which is named as an excitation current pulse, and denoted as I_{exc}. In this embodiment, the current density of I_{exc} is about 10⁷ A/cm². With the excitation of this current, the spin current generation layer generates a sufficiently strong spin polarization current to create a spin-orbit moment on the nanomagnetic material layer, thereby changing the direction of the magnetic moment of the nanomagnetic material layer. That is, under the torque, the magnetization vector of the nanomagnet is deflected from a direction perpendicular to the film (nanomagnetic material layer) to hard axis, which is in-plane and perpendicular to the current direction, then after the excitation current is removed, the magnetization state of the nanomagnet changes to an unstable high-energy state. Thus, due to the influence of thermal perturbation, it can fully randomly return from hard axis to one of the two states, upward or downward magnetization perpendicular to the film. When there is no external magnetic field, the probability of returning to either of these two states is equal, which is 0.5, as shown in FIG. 7. When there is an external magnetic field, for the first magnetic sensor structure, a small current pulse can be applied on the same channel of the spin current generation layer, which is named as a read current pulse, denoted as Lad. In this embodiment, it is about 10⁵ A/cm². The application of this current does not affect the magnetization state of the nanomagnet. The anomalous Hall voltage can be measured across the spin current generation layer, as shown in FIG. 8. Thus, the magnetization state of the nanomagnet can be detected by the magnitude of the voltage.

For the second and third magnetic sensor structures, a z direction read current pulse I_{read}, which passes through the tunnel junction or the spin valve from top to bottom, is applied to detect the state of the nanomagnet due to the tunneling magnetoresistance effect or giant magnetoresistance effect. Thus, the magnetization state of the nanomagnet in the spin current generation layer can be detected by the resistance, as shown in FIG. 9 and FIG. 10.

When there is an external magnetic field, the presence of the magnetic field can cause the magnetization to return to a certain state with a specific probability. In this embodiment, the probability of the downward magnetization direction state is selected for the test.

The probability and the magnitude of the magnetic field conform to a specific relationship, which can be obtained by pre-applying a known magnetic field in the present invention. As shown in FIG. 12 and FIG. 13, the vertical ordinate P in the figure represents the probability that the magnetization of the nanomagnet obtained statistically is downward after the excitation current is applied. Each data point is a statistical result of multiple excitation current pulses. The horizontal ordinates Hₓ, H_{y} and H_{z} represent the magnitudes of the applied magnetic fields along the x, y, and z axes, respectively. The gray dots in the figure represent the probability that the excitation current is applied in the positive direction of the x-axis or the y-axis. The black dots represent the statistical probability that the applied excitation current is in the negative x-axis or y-axis direction. At the same time, it can be seen that when the magnetic field is small, the magnitude of the magnetic field and the probability have an approximately linear relationship, which is easy to use.

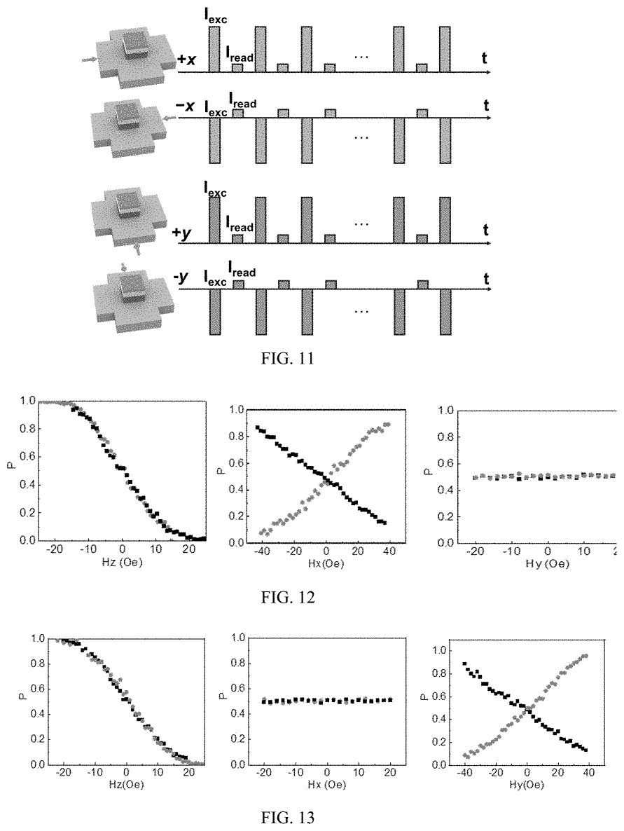

Specifically, in the present invention, after each excitation current pulses a small current pulse is applied after each excitation current pulse for state reading. This small current is not big enough to change the magnetization state of the nanomagnet. That is, the excitation current pulse I_{exc} and the read current pulse Lad are alternately applied and repeated a number of times, as shown in FIG. 11. For the first magnetic sensor structure in the present invention, by means of generating the anomalous Hall effect, the magnetization state can be detected by the magnitude of the anomalous Hall voltage. For the second and third magnetic sensor structures in the present invention, a z direction read current pulse bead, which passes through the tunnel junction or the spin valve from top to bottom, is applied to detect the state of the nanomagnet due to the tunneling magnetoresistance effect or giant magnetoresistance effect. Thus, the magnetization state of the nanomagnet in the spin current generation layer can be detected by the resistance.

With the assistance of specific circuits such as comparators and counters, the probability of the occurrence of a certain state can be calculated. In this embodiment, the probability of the downward magnetization state of the nanomagnet is calculated. According to the probability, the magnitude and direction of the detection magnetic field, the relationship between the probability of a certain magnetization state and the components in the three directions of the magnetic field vector can be obtained. Preferably, the probability and the magnitude of the detection magnetic field satisfy the Sigmoid function relationship. The relationship between the probability of a certain magnetization state and the components in the three directions of the magnetic field vector can be obtained based on the probability, the magnitude of the detection magnetic field, and the relationship between the probability and the magnitude of the detection magnetic field satisfying the Sigmoid function.

When measuring the three-dimensional magnetic field vector in any direction, the magnetic field vector can be regarded as the superposition of the magnetic field vectors along the three directions of x, y, and z, and its effect on the probability can also be superimposed. Based on FIG. 12 and FIG. 13, it can be seen that when the excitation current is applied to the positive and negative directions of the x-axis respectively, the effect of applying a magnetic field in the x-direction on the probability, that is, the trend of the probability change, is that the two have the characteristics of equal size and opposite direction. Applying a magnetic field in the z direction can result in the same change in probability, while applying a magnetic field in the y direction has no effect on the probability. Therefore, when Hₓ, H_{y}, and H_{z} exist at the same time, the probability can be added by applying the excitation current in both the positive and negative directions of the x-axis at the same time to add the probabilities thereof. This can counteract the effect of the magnetic field applied in the x direction. Thus, the resulting probability sum is only related to the applied magnetic field in the z direction. Therefore, we can obtain the relationship between the calculated probability P₁ and the component of the magnetic field vector along the z direction. By subtracting the probabilities, the magnetic field applied in the z direction can be counteracted, and the resulting probability difference is only related to the magnetic field applied in the x direction. Therefore, we can obtain the relationship between the calculated probability P₂ and the component of the magnetic field vector along the x direction.

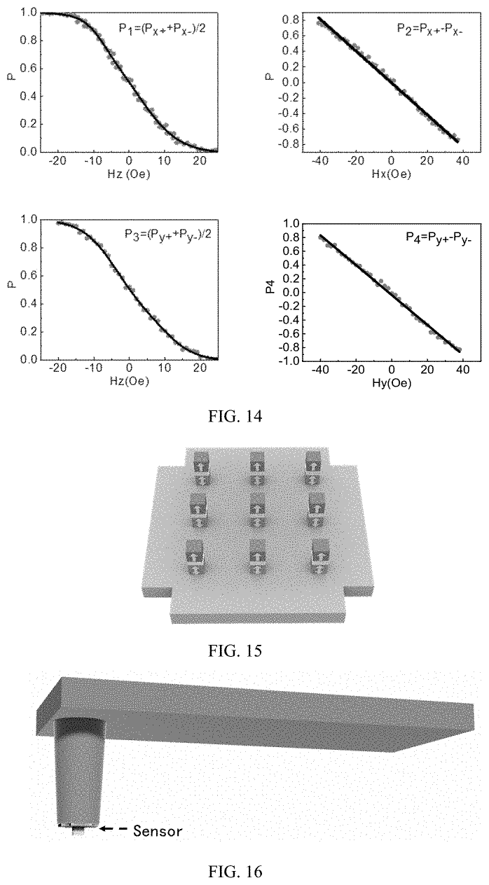

In the same way, an excitation current can be applied in the positive and negative directions of y respectively, and the probabilities thereof can be added to counteract the effect of the magnetic field applied in the y direction. The resulting probability sum is only related to the magnetic field applied in the z direction. Therefore, we can obtain the relationship between the calculated probability P₃ and the component of the magnetic field vector along the z direction. In addition, by subtracting the probabilities, the effect of the magnetic field applied in the z direction can be counteracted, and the obtained probability sum is only related to the magnetic field applied in the y direction. Therefore, we can obtain the relationship between the calculated probability P₄ and the component of the magnetic field vector along the y direction. In this way, the function of measuring any magnetic field vector can be achieved. By bringing the probabilities P₁, P₂ and P₄ into the above-mentioned functional relationship obtained based on the detection magnetic field, the magnitude of the three components of any magnetic field can be obtained. Next, through vector synthesis, the magnetic field vector can be obtained, as shown in FIG. 14.

Specifically, the three-dimensional magnetic field measurement method of the present invention includes the following steps:
excite the random process of the magnetization of the nanomagnet and read the final state: in the cross channel of the spin current generation layer, a large current pulse is applied to the positive and negative directions of the x-axis and the y-axis, respectively, where the current pulse is referred to as an excitation current pulse; the excitation current pulse causes the spin current generation layer to generate a spin polarized current, which applies a spin-orbit torque to the nanomagnet, thereby changing the direction of the magnetic moment of the nanomagnet to hard axis; after the excitation current pulse is removed, under the action of the external magnetic field, the magnetization state of the nanomagnet randomly returns to be perpendicular to a surface thereof upward or downward with a certain probability; next a small current pulse is applied, which is referred to as a read current pulse, and the anomalous Hall voltage across the spin current generation layer, the resistance of the magnetic tunnel junction, or the resistance of the spin valve is measured so as to determine the magnetization of the nanomagnet state; the operation of the random process of exciting and reading the magnetization state of the nanomagnet is then repeated;
calculate the probability: the number of occurrences of a certain magnetization state is counted, and then the probability of the magnetization state when the excitation current pulse is applied in a corresponding direction is calculated, which are denoted as Pₓ₊, Pₓ₋, P_{y+}, P_{y-} respectively; the probabilities Pₓ₊ and Pₓ₋ are then added to get the probability P₁ of the magnetization state in a case equivalent to a magnetic field being applied in the z direction; the probability Pₓ₋ is subtracted from the probability Pₓ₊ to get the probability P₂ of the magnetization state in a case equivalent to a magnetic field being applied in the x direction; the probabilities P_{y+} and P_{y-} are added to get the probability P₃ of the magnetization state in a case equivalent to a magnetic field being applied in the z direction; and the probability of P_{y-} is subtracted from the probability P_{y+} to get the probability P₄ of the magnetization state in a case equivalent to a magnetic field being applied in the y direction; in this embodiment, P₁=(Pₓ₊+Pₓ₋)/2, P₂=Pₓ₊−Pₓ₋, P₃=(P_{y+}+P_{y-})/2, and P₄=P_{y+}−P_{y-}; at the same time, It can be seen that both P₁ and P₃ represent the functional relationship between the z-direction magnetic field components and the probability, and theoretically P₁=P₃;
calculate the magnetic field vector: the probabilities P₁, P₂ and P₄ are brought into the functional relationship between the probability of the occurrence of the magnetization state and the magnetic field vector to obtain the magnitude of the external magnetic field in three directions; and then through vector synthesis, the magnetic field vector can be obtained, as shown in FIG. 14.

The functional relationship between the probability of the occurrence of the magnetization state and the magnetic field vector can be obtained by pre-applying a detection magnetic field, which can include the following steps:
step S1, apply an excitation currents pulse to the positive direction and negative direction of the x-axis, and the positive direction and negative direction of the y-axis respectively;
step S2, in each current direction, apply a detection magnetic field to the x, y, and z directions respectively;
step S3: calculate the probability of a certain magnetization state when the detection magnetic field is applied to the x, y, and z directions respectively in each current direction, and then establish a relationship between the probability and the magnitude and direction of the detection magnetic field;
step S4, based on the relationship, obtain a functional relational formula between the probability of the occurrence of the magnetization state and the magnetic field vector.

As shown in FIG. 15, based on the magnetic sensor provided above, the present invention further provides an array magnetic sensor, which is composed of a plurality of the above magnetic sensors. In the array magnetic sensor, the spin current generation layer is shared. The average operating speed of a large number of devices in an array can be accelerated by applying an excitation current to drive all magnetic sensors simultaneously.

As shown in FIG. 16, based on the magnetic sensor provided above, the present invention also provides a scanning probe with the function of mapping three-dimensional magnetic field, in which the above magnetic sensor is disposed on the tip of an atomic force microscope probe or other probes. The closer the magnetic sensor is to the sample, the stronger the perceived magnetic field, the more accurate the detection will be, and the finer detectable details and resolved structures will be. The sensor is placed close to the surface of the sample with the aid of an atomic force microscope, and the surface magnetic field is measured while measuring the surface topography of the material. In this way, the magnetic information on the surface of the sample is plotted, which has higher accuracy and flexibility.

The magnetic sensor of the present invention is a nanoscale device. The existing industrial practice has proved that the size can reach at least thirty nanometers. Moreover, it is theoretically predicted that the size can be further reduced to about ten nanometers through improvements in material technology. Therefore, the magnetic field sensor of the present invention can achieve a very small size, thereby achieving ultra-high spatial resolution. The present invention expands the application potential in many fields such as chip integration, microscopic magnetic detection, magnetic imaging, magnetic positioning, and molecular magnetic detection.

The present invention is based on the working mode of spin-related effects (spin-orbit torque, anomalous Hall effect, tunneling magnetoresistance effect, and giant magnetoresistance effect), the time of a single current pulse can reach nanoseconds, and then high-speed measurement can be performed. In addition, the higher the number of current pulses applied, the more accurate the probability of the measurement, the more accurate the probability obtained by statistics, and the more accurate the obtained magnetic field vector result. At the same time, the method of the present invention can perform the magnetic field vector measurement at a room temperature, which solves the technical problem in the existing technologies that the measurement needs to be performed at a very low temperature.

The structure and process of the magnetic sensor of the present invention are relatively simple. High-density sensor arrays can be easily fabricated by sharing spin current generation layers. The spacing between devices can be reduced to tens of nanometers. The present invention can be used for magnetic field measurements or magnetic imaging in a large spatial range. It can also be integrated into the probe tip of an atomic force microscope for scanning magnetic information on the surface of materials.

With a single magnetic sensor, the three spatial components of the three-dimensional magnetic field vector can be measured. Compared with the existing technologies, it has the effect of reducing the number and complexity of devices for measuring the magnetic field vector.

A person skilled in the art can easily understand that the above descriptions are only some preferred embodiments of the present invention, and are not intended to limit the present invention. Any modifications, equivalent replacements and improvements made within the principle of the present invention shall be included within the scope of protection of the present invention.

1. A nanometer three-dimensional magnetic sensor with all-electric operation, wherein from bottom to top, the magnetic sensor comprises: a spin current generation layer, a magnetic material layer, and an oxide layer; the spin current generation layer comprises a cross-shaped conductive channel for conducting current; the magnetic material layer is a single magnetic domain nanomagnet and has magnetic anisotropy perpendicular to a surface thereof under an action of the oxide layer;
or from bottom to top, the magnetic sensor comprises: a spin current generation layer, a free layer, a tunneling layer, and a fixed layer; the free layer, the tunneling layer and the fixed layer constitute a magnetic tunnel junction, and the free layer is a single magnetic domain nanomagnet with magnetic anisotropy perpendicular to a surface thereof;
or from bottom to top, the magnetic sensor comprises: a spin current generation layer, a first magnetic layer, a non-magnetic intermediate layer, a second magnetic layer, and a pinning layer; the first magnetic layer, the non-magnetic intermediate layer, the second magnetic layer and the pinning layer constitute a spin valve, and the first magnetic layer is a single magnetic domain nanomagnet with magnetic anisotropy perpendicular to a surface thereof.

2. The magnetic sensor according to claim 1, wherein a protective layer is further provided on the oxide layer for isolating air.

3. The magnetic sensor according to claim 1, wherein a material of the spin current generation layer is a heavy metal material or a topological insulator material.

4. The magnetic sensor according to claim 1, wherein a material of the nanomagnet is CoFeB, CoMnSi, CoFeSi, CoFeAl, GaMnAs, CoFeAlSi, CoFe, FePt, CoPt, FeNi, Fe, Co, or Ni.

5. The magnetic sensor according to claim 1, wherein a material of the oxide layer is MgO or Al₂O₃;
a material of the tunneling layer is MgO, Al₂O₃, AlOₓ, TiO₂, HfO₂, MgAlO₄, AlN, or BN;
a material of the first magnetic layer and the second magnetic layer is CoFeB, CoMnSi, CoFeSi, CoFeAl, GaMnAs, CoFeAlSi, CoFe, FePt, CoPt, FeNi, Fe, Co, or Ni;
a material of the non-magnetic intermediate layer is Cu, Cr, Ru, or Ag; and
a material of the pinning layer is FeMn, IrMn, NiMn, PtMn, or NiO.

6. A three-dimensional magnetic field measurement method, wherein the magnetic sensor according to claim 1 is used in the method, and the method comprises:
establishing a three-dimensional rectangular coordinate system: establishing a three-dimensional rectangular coordinate system with a direction of the cross-shaped conductive channel as an x-axis and a y-axis thereof, and a direction perpendicular to a surface of the spin current generation layer as a z-axis;
in the cross channel of the spin current generation layer, applying an excitation current pulse to a positive direction and a negative direction of the x-axis and the y-axis respectively, so that the spin current generation layer generates a spin-polarized current; applying a spin-orbit torque to the nanomagnet, so that a direction of the magnetic moment of the nanomagnet is tuned to hard axis; removing the excitation current pulse, and under an external magnetic field, the magnetization state of the nanomagnet randomly returning to be perpendicular to the surface thereof upward or downward with a certain probability; and then adding a read current pulse to measure an anomalous Hall voltage at both ends of the spin current generation layer, the resistance of the magnetic tunnel junction, or the resistance of the spin valve to determine the magnetization state of the nanomagnet; and repeating the foregoing operation;
calculating probabilities: counting a number of occurrences of a certain magnetization state, and then calculating probabilities of the occurrence of certain magnetization states when the excitation current pulse is applied in corresponding directions, which are denoted as Pₓ₊, Pₓ₋, P_{y+}, P_{y-} respectively; adding the probabilities Pₓ₊ and Pₓ₋ to get a probability P₁ of the magnetization state in a case equivalent to a magnetic field being applied in the z direction; subtracting the probability Pₓ₋ from the probability Pₓ₊ to get a probability P₂ of the magnetization state in a case equivalent to a magnetic field being applied in the x direction; and subtracting the probability of P_{y-} from the probability P_{y+} to get the probability P₄ of the magnetization state in a case equivalent to a magnetic field being applied in the y direction; and
calculating a magnetic field vector: bringing the probabilities P₁, P₂ and P₄ into a functional relationship between the probability of the occurrence of the magnetization state and the magnetic field vector to obtain the magnitudes of the external magnetic field in three directions; and then through vector synthesis, obtaining the magnetic field vector.

7. The method according to claim 6, wherein the functional relationship between the probability of the occurrence of the magnetization state and the magnetic field vector is obtained by pre-applying a detection magnetic field, comprising the following steps:
step S1, applying an excitation current pulse to the positive direction and negative direction of the x-axis, and the positive direction and negative direction of the y-axis respectively;
step S2, in each current direction, applying a detection magnetic field to the x, y, and z directions respectively;
step S3: calculating a probability of a certain magnetization state when the detection magnetic field is applied to the x, y, and z directions respectively in each current direction, and then establishing a relationship between the probability and the detection magnetic field; and
step S4, based on a relational formula, obtaining a functional relational formula between the probability and the magnetic field vector.

8. The method according to claim 7, wherein when measuring the anomalous Hall voltage, the position and direction for applying the read current pulse are the same as those of the excitation current pulse; and when measuring the resistance of the magnetic tunnel junction or the resistance of the spin valve, the read current pulse is applied to the tunnel junction or the spin valve in the z-axis direction.

9. A nanometer three-dimensional magnetic sensor array with all-electric operation, wherein the magnetic sensor array comprises a plurality of magnetic sensors according to claim 1, and the plurality of the magnetic sensors share a single spin current generation layer.

10. A scanning probe with the function of mapping three-dimensional magnetic field, wherein the magnetic sensor according to claim 1 is integrated on a probe.
